(19) United States
(12) Patent Application Publication
(10) Pub. No.: US 2025/0107382 A1
(43) Pub. Date: Mar. 27, 2025

(54) DISPLAY PANEL AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventors: Xi XIAO, Shenzhen (CN); Guangyao LI, Shenzhen (CN); Baixiang HAN, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 18/895,463

(22) Filed: Sep. 25, 2024

(30) Foreign Application Priority Data
Sep. 26, 2023 (CN) 202311251122.3

(51) Int. Cl. H10K 59/35; H10K 59/122

(52) U.S. Cl. CPC H10K 59/353; H10K 59/122

(57) ABSTRACT

A display panel and a display device are provided. First pixel units in each of first pixel unit rows are misaligned with first pixel units of an adjacent first pixel unit row along a first direction. First pixel units in each of first pixel unit columns are misaligned with first pixel units of an adjacent first pixel unit column along a second direction. A projection of the first pixel units of one of the first pixel unit rows at least partially overlaps with a projection of second pixel units and third pixel units of an adjacent second pixel unit row along the first direction. A projection of the first pixel units of one of the first pixel unit columns at least partially overlaps with a projection of second pixel units and third pixel units of an adjacent second pixel unit column along the second direction.

### CROSS-REFERENCE TO RELATED APPLICATION

This application claims priority to Chinese Patent Application No. 202311251122.3, filed on Sep. 26, 2023, the disclosure of which is incorporated herein by reference in its entirety.

### TECHNICAL FIELD

The present application relates to a technical field of display, and in particular, to a display panel and a display device.

### BACKGROUND

Compared with liquid crystal display panels, organic light-emitting diode (OLED) display panels have advantages of being thinner and lighter, better display effect, higher resolution, wider color gamut, lower power consumption, and being able to achieve flexible display. The OLED display panels have developed rapidly in recent years and have become a preferred type of display panels for mobile terminals.

In related art, one of preparation methods of pixel unit arrays of the OLED display panels is inkjet printing. The inkjet printing has more advantages in display due to low requirements for production environment and low cost. At present, higher requirements for a resolution of the OLED display panels have been put forward by users. However, limited by a machine accuracy of an existing inkjet printing process, it is difficult for the OLED display panels to balance layout areas of pixel units on a basis of ensuring the resolution, resulting in a technical problem that the OLED display panels with high resolution has a greater printing difficulty. The technical problem urgently needs to be solved.

### SUMMARY

In one aspect, a display panel provided by the present application includes a substrate and a pixel unit array arranged on the substrate. The pixel unit array includes a plurality of first pixel unit rows sequentially arranged along a first direction and a plurality of first pixel unit columns sequentially arranged along a second direction. Each of the first pixel unit rows includes a plurality of first pixel units sequentially arranged along the second direction. Each of the first pixel unit columns includes a plurality of first pixel units sequentially arranged along the first direction. The pixel unit array further includes a plurality of second pixel unit rows sequentially arranged along the first direction and a plurality of second pixel unit columns sequentially arranged along the second direction. Each of the second pixel unit rows includes a plurality of second pixel units and a plurality of third pixel units alternately arranged along the second direction. Each of the second pixel unit columns includes a plurality of second pixel units and a plurality of third pixel units alternately arranged along the first direction. The first pixel units in each of the first pixel unit rows are misaligned with the first pixel units of an adjacent first pixel unit row along the first direction. The first pixel units in each of the first pixel unit columns are misaligned with the first pixel units of an adjacent first pixel unit column along the second direction. One of the second pixel unit rows is arranged between every adjacent two of the first pixel unit rows. A projection of the first pixel units of one of the first pixel unit rows at least partially overlaps with a projection of the second pixel units and the third pixel units of an adjacent second pixel unit row along the first direction. One of the second pixel unit columns is arranged between every adjacent two of the first pixel unit columns. A projection of the first pixel units of one of the first pixel unit columns at least partially overlaps with a projection of the second pixel units and the third pixel units of an adjacent second pixel unit column along the second direction.

In a second aspect, a display device provided by the present application includes a housing and the display panel mentioned above. The housing includes an accommodating space. The display panel is disposed inside the accommodating space.

### BRIEF DESCRIPTION OF THE DRAWINGS

In order to more clearly explain technical solutions in specific embodiments of the present application or the prior art, the drawings needed to be used in the description of the specific embodiments or the prior art will be briefly introduced below. It is obvious that the drawings in the following description illustrate some embodiments of the present application. For those of ordinary skill in the art, other drawings may be obtained based on these drawings without creative efforts.

FIG. 1 is a schematic plan view of a pixel unit array according to some embodiments of the present application.

FIG. 2 is another schematic plan view of the pixel unit array according to some embodiments of the present application.

FIG. 3 is a partial enlarged view of a display panel according to some embodiments of the present application.

FIG. 4 is a schematic cross-sectional view of the display panel in FIG. 3 unfolded along a line AB.

### REFERENCE NUMBERS

10, substrate; 20, pixel unit array; 101, first pixel unit row; 102, second pixel unit row; 201, first pixel unit column; 202, second pixel unit column; 21, first pixel unit; 211, first pixel sub-unit; 22, second pixel unit; 221, second pixel sub-unit; 23, third pixel unit; 231, third pixel sub-unit; 24, first edge pixel unit; 30, first pixel definition layer; 31, first bam; 32, second dam; 33, third dam; 40, second pixel definition layer; 50, anode layer; 51, first anode unit; 511, first guide part; 512, first contact hole defining area; 52, second anode unit; 521, second guide part; 522, second contact hole defining area; 53, third anode unit; 531, third guide part; 532, third contact hole defining area; X, first direction; Y, second direction; M, rectangular pixel area; N, pixel definition opening.

### DETAILED DESCRIPTION

Technical solutions in embodiments of the present application will be described clearly and completely hereafter with reference to accompanying drawings. Apparently, the described embodiments are only a part of but not all embodiments of the present application. All other embodiments obtained by persons of ordinary skill in the art based on the embodiments of the present application without creative efforts shall fall within a protection scope of the present application. In addition, it should be understood that the detailed description described herein is for illustration and explanation of the present application only, and is not intended to limit the present application. In the present application, unless stated to the contrary, the location words used such as “upper” and “lower” usually refer to the upper and lower in the actual use or working state of the device, specifically the drawing direction in the accompanying drawings. While “inner” and “outer” are for the outline of the device.

Various embodiments and examples are provided in the following description to implement different structures of the present application. In order to simplify the present disclosure, certain elements and settings will be described. However, these elements and settings are only by way of example and are not intended to limit the present application. In addition, reference numerals may be repeated in different examples in the present application. This repeating is for the purpose of simplification and clarity and does not refer to relations between different embodiments and/or settings. Furthermore, examples of different processes and materials are provided in the present application. However, it would be appreciated by those skilled in the art that other processes and/or materials may be also applied. Hereinafter, each of the embodiments will be described in detail. It should be noted that the order in which the following embodiments are described is not intended to limit the preferred order of the embodiments.

A display panel is provided by the present application. The display panel includes a substrate and a pixel unit array arranged on the substrate. The pixel unit array includes a plurality of first pixel unit rows sequentially arranged along a first direction and a plurality of first pixel unit columns sequentially arranged along a second direction. Each of the first pixel unit rows includes a plurality of first pixel units sequentially arranged along the second direction. Each of the first pixel unit columns includes a plurality of first pixel units sequentially arranged along the first direction. The pixel unit array further includes a plurality of second pixel unit rows sequentially arranged along the first direction and a plurality of second pixel unit columns sequentially arranged along the second direction. Each of the second pixel unit rows includes a plurality of second pixel units and a plurality of third pixel units alternately arranged along the second direction. Each of the second pixel unit columns includes a plurality of second pixel units and a plurality of third pixel units alternately arranged along the first direction. The first pixel units in each of the first pixel unit rows are misaligned with the first pixel units of an adjacent first pixel unit row along the first direction. The first pixel units in each of the first pixel unit columns are misaligned with the first pixel units of an adjacent first pixel unit column along the second direction. One of the second pixel unit rows is arranged between every adjacent two of the first pixel unit rows. A projection of the first pixel units of one of the first pixel unit rows at least partially overlaps with a projection of the second pixel units and the third pixel units of an adjacent second pixel unit row along the first direction. One of the second pixel unit columns is arranged between every adjacent two of the first pixel unit columns. A projection of the first pixel units of one of the first pixel unit columns at least partially overlaps with a projection of the second pixel units and the third pixel units of an adjacent second pixel unit column along the second direction.

In some embodiments, a periphery of each of the first pixel units is provided with two second pixel units and two third pixel units. The two second pixel units and the two third pixel units are adjacent to a corresponding one of the first pixel units. An area of at least one of each of the two second pixel units and each of the two third pixel units is greater than an area of the corresponding one of the first pixel units.

In some embodiments, the two second pixel units are arranged symmetrically about one of diagonal lines of the corresponding one of the first pixel units, and the two third pixel units are arranged symmetrically about the other one of diagonal lines of the corresponding one of the first pixel units.

In some embodiments, the substrate includes a plurality of rectangular pixel partitions arranged in an array. Each of the first pixel units corresponds to two rectangular pixel partitions, and an area of each of the first pixel units in each of the two rectangular pixel partitions is equal. Each of the second pixel units corresponds to two rectangular pixel partitions, and an area of each of the second pixel units in each of the two rectangular pixel partitions is equal. Each of the third pixel units corresponds to two rectangular pixel partitions, and an area of each of the third pixel units in each of the two rectangular pixel partitions is equal.

In some embodiments, each of the first pixel units includes two first pixel sub-units independently emitting light, and areas of the two first pixel sub-units in corresponding rectangular pixel partitions are equal. Each of the second pixel units includes two second pixel sub-units independently emitting light, and areas of the two second pixel sub-units in corresponding rectangular pixel partitions are equal. Each of the third pixel units includes two third pixel sub-units independently emitting light, and areas of the two third pixel sub-units in corresponding rectangular pixel partitions are equal.

In some embodiments, the display panel further includes a first pixel definition layer disposed on the substrate. The first pixel definition layer includes a plurality of first dams, a plurality of second dams, and a plurality of third dams. One of the first dams is arranged between the two first pixel sub-units of each of the first pixel units. One of the second dams is arranged between the two second pixel sub-units of each of the second pixel units. One of the third dams is arranged between the two third pixel sub-units of each of the third pixel units. The first pixel definition layer is made of a hydrophilic material.

In some embodiments, a length direction of each of the first dams is parallel to a width direction of a corresponding one of the first pixel units. A width of the corresponding one of the first pixel units is a first width. A length direction of each of the second dams is parallel to a width direction of a corresponding one of the second pixel units. A width of the corresponding one of the second pixel units is a second width. A length direction of each of the third dams is parallel to a width direction of a corresponding one of the third pixel units. A width of the corresponding one of the third pixel units is a third width. The first width, the second width, and the third width are equal.

In some embodiments, the first width, the second width, and the third width are each greater than 30 μm.

In some embodiments, the display panel further includes a second pixel definition layer disposed on the substrate. The second pixel definition layer and the first pixel definition layer together form a plurality of pixel definition openings. The first pixel sub-units, the second pixel sub-units, and the third pixel sub-units are correspondingly arranged within the pixel definition openings. The second pixel definition layer is made of a hydrophobic material.

In some embodiments, a minimum pitch between the first pixel units and the second pixel units is a, and a minimum pitch between the first pixel units and the third pixel units is b. Where the a is equal to the b and greater than or equal to a preset value. The preset value ranges from 10 μm to 15 μm.

A display device provided by the present application includes a housing and the display panel mentioned above. The housing includes an accommodating space. The display panel is disposed inside the accommodating space.

The beneficial effects of the present application are illustrated as follows. The present application provides a display panel and a display device. The display panel adopts a specific arrangement of pixel units, so that the adjacent first pixel units are misaligned along the first direction and the second direction, the first pixel units of one of the first pixel unit rows at least partially overlap with the second pixel units and the third pixel units of the adjacent second pixel unit row along the first direction, and the first pixel units of one of the first pixel unit columns at least partially overlap with the second pixel units and the third pixel units of the adjacent second pixel unit column along the first direction. On the basis of ensuring a resolution of the display panel, a layout area of the pixel units is increased in limited layout space, thereby reducing a process difficulty of forming the first pixel units, the second pixel units, and the third pixel units of the display panel by inkjet printing, and improving a production yield.

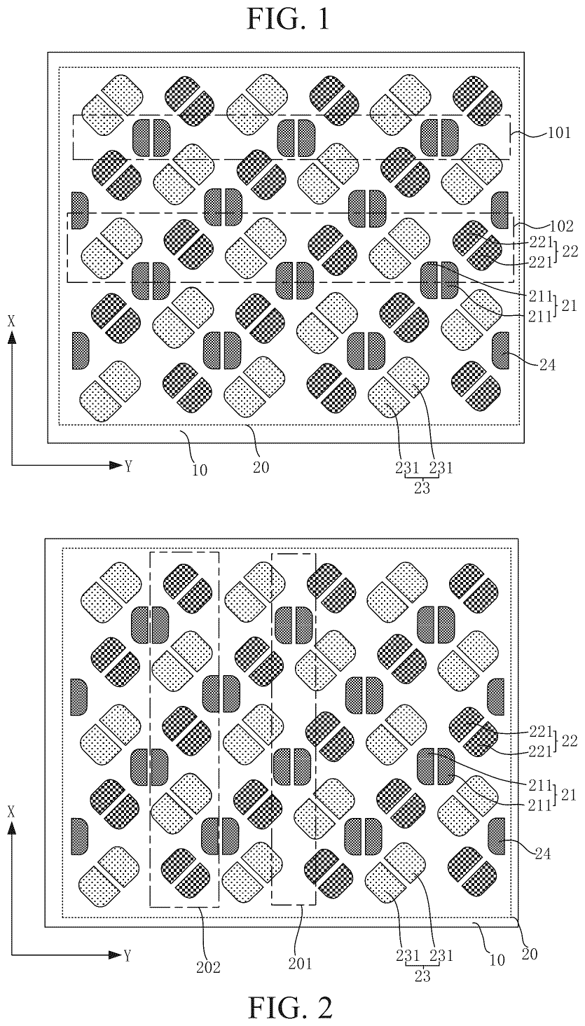

FIG. 1 is a schematic plan view of a pixel unit array according to some embodiments of the present application. FIG. 2 is another schematic plan view of the pixel unit array according to some embodiments of the present application. Referring to FIG. 1 and FIG. 2, in a first aspect, the present application provides a display panel. The display panel includes a substrate 10 and a pixel unit array 20 arranged on the substrate 10. The pixel unit array 20 includes a plurality of first pixel unit rows 101 sequentially arranged along a first direction X and a plurality of first pixel unit columns 201 sequentially arranged along a second direction Y. Each of the first pixel unit rows 101 includes a plurality of first pixel units 21 sequentially arranged along the second direction Y. Each of the first pixel unit columns 201 includes a plurality of first pixel units 21 sequentially arranged along the first direction X. The pixel unit array 20 further includes a plurality of second pixel unit rows 102 sequentially arranged along the first direction X and a plurality of second pixel unit columns 202 sequentially arranged along the second direction Y. Each of the second pixel unit rows 102 includes a plurality of second pixel units 22 and a plurality of third pixel units 23 alternately arranged along the second direction Y. Each of the second pixel unit columns 202 includes a plurality of second pixel units 22 and a plurality of third pixel units 23 alternately arranged along the first direction X.

One of the second pixel unit rows 102 is arranged between every adjacent two of the first pixel unit rows 101. The first pixel units 21 in each of the first pixel unit rows 101 are misaligned with the first pixel units 21 of an adjacent first pixel unit row 101 along the first direction X. A projection of the first pixel units 21 of one of the first pixel unit rows 101 at least partially overlaps with a projection of the second pixel units 22 and the third pixel units 23 of an adjacent second pixel unit row 102 along the first direction X.

One of the second pixel unit columns 202 is arranged between every adjacent two of the first pixel unit columns 201. The first pixel units 21 in each of the first pixel unit columns 201 are misaligned with the first pixel units 21 of an adjacent first pixel unit column 201 along the second direction Y. A projection of the first pixel units 21 of one of the first pixel unit columns 201 at least partially overlaps with a projection of the second pixel units 22 and the third pixel units 23 of an adjacent second pixel unit column 202 along the second direction Y.

In the display panel provided by the present application, since the first pixel units 21 in each of the first pixel unit rows 101 are misaligned with the first pixel units 21 of the adjacent first pixel unit row 101 along the first direction X, and the first pixel units 21 in each of the first pixel unit columns 201 are misaligned with the first pixel units 21 of the adjacent first pixel unit column 201 along the second direction Y, so that the display panel adopts an arrangement in which the first pixel units 21 are misaligned along the first direction X and the second direction Y. On a basis of ensuring a layout number of the first pixel units 21 and a resolution of the display panel, the first pixel units 21 each has a larger size along the first direction X and the second direction Y, thereby reducing a difficulty of printing the first pixel units 21, and reserving layout space for the second pixel units 22 and the third pixel units 23.

Furthermore, one of the second pixel unit rows 102 is arranged between every adjacent two of the first pixel unit rows 101. The projection of the first pixel units 21 of one of the first pixel unit rows 101 at least partially overlaps with the projection of the second pixel units 22 and the third pixel units 23 of the adjacent second pixel unit row 102 along the first direction X. One of the second pixel unit columns 202 is arranged between every adjacent two of the first pixel unit columns 201. The projection of the first pixel units 21 of one of the first pixel unit columns 201 at least partially overlaps with the projection of the second pixel units 22 and the third pixel units 23 of the adjacent second pixel unit column 202 along the second direction Y. So such, the display panel adopts an arrangement in which the second pixel units 22 and the third pixel units 23 are obliquely arranged, so that on a basis of ensuring a layout number of the second pixel units 22 and the third pixel units 23 and the resolution of the display panel, the second pixel units 22 and the third pixel units 23 can more fully utilize the space along the first direction X and the second direction Y, and a size of each of the second pixel units 22 and the third pixel units 23 is widened, thereby reducing a difficulty of printing the second pixel units 22 and the third pixel units 23.

In some embodiments of the present application, a minimum pitch between the first pixel units and the second pixel units is defined as a, and a minimum pitch between the first pixel units and the third pixel units is defined as b. The a is equal to the b and greater than or equal to a preset value.

In the display panel provided by the present application, the preset value ranges from 10 μm to 15 μm, such as 12 μm. Specifically, limited by accuracy requirements of inkjet printing devices, the minimum pitch a between the first pixel units 21 and the second pixel units 22 should be no less than the preset value, and the minimum pitch b between the first pixel units 21 and the third pixel units 23 should be no less than the preset value. In the present application, the two pixel units and the third pixel units 23 are obliquely arranged, so that on the basis of ensuring that both the a and the b are greater than or equal to the preset value, the display panel having the resolution that meets requirements of users and having larger sizes of the pixel units can be manufactured by using the inkjet printing devices with an existing design accuracy.

In some embodiments of the present application, a periphery of each of the first pixel units 21 is provided with two second pixel units 22 and two third pixel units 23, and the two second pixel units 22 and the two third pixel units 23 are adjacent to a corresponding one of the first pixel units 2. An area of at least one of each of the two second pixel units 22 and each of the two third pixel units 23 is greater than an area of the corresponding one of the first pixel units 21.

In the display panel provided by the present application, the area of at least one of each of the two second pixel units 22 and each of the two third pixel units 23 is greater than the area of the corresponding one of the first pixel units 21. That is, the first pixel units 21 are not pixel units having the largest sizes among three types of pixel units. In the present application, the first pixel units 21 having small or medium sizes are used as center pixel units, and the two second pixel units 22 and the two third pixel units 23 surround the periphery of the corresponding one of the first pixel units 21, so that an arrangement density of the three types of pixel units is largest, and the resolution of the display panel is further improved.

In some embodiments of the present application, the two second pixel units 22 are arranged symmetrically about one of diagonal lines of the corresponding one of the first pixel units 21, and the two third pixel units 23 are arranged symmetrically about the other one of diagonal lines of the corresponding one of the first pixel units 21.

In the display panel provided by the present application, the first pixel units 21, the second pixel units 22, and the third pixel units 23 are all rectangular-shaped or quasi-rectangular-shaped. Each type of the pixel units each has two diagonal lines. In the present application, the two second pixel units 22 are arranged symmetrically about one of diagonal lines of the corresponding one of the first pixel units 21, and the two third pixel units 23 are arranged symmetrically about the other one of diagonal lines of the corresponding one of the first pixel units 21, so that distribution of relative positions of the second pixel units 22 and the first pixel units 21 can be more regular, and distribution of relative positions of the third pixel units 23 and the first pixel units 21 can be more regular, which is beneficial to improving an alignment accuracy and printing efficiency of inkjet printing.

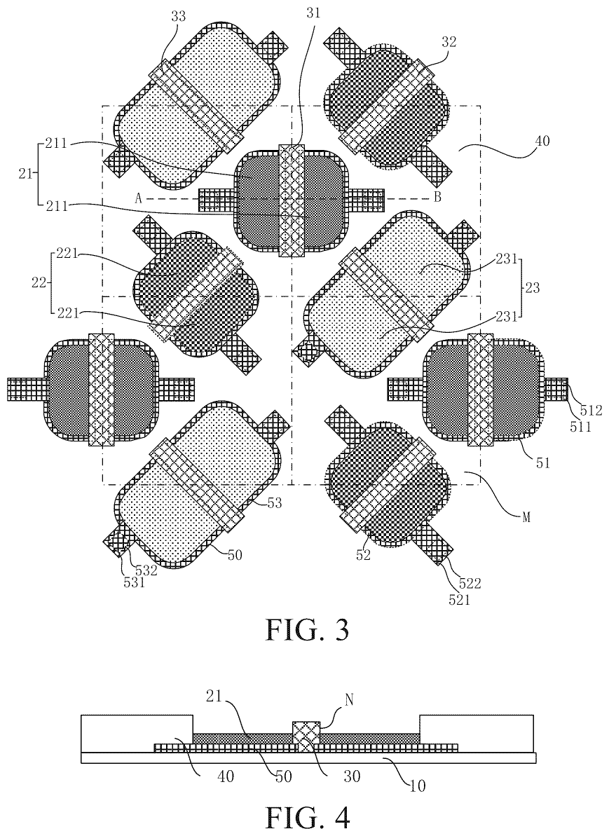

FIG. 3 is a partial enlarged view of a display panel according to some embodiments of the present application. Referring to FIG. 3, in some embodiments of the present application, the substrate 10 is evenly divided into a plurality of rectangular pixel partitions arranged in an array. Each of the first pixel units 21 corresponds to two rectangular pixel partitions, and an area of each of the first pixel units 21 in each of the two rectangular pixel partitions is equal. Each of the second pixel units 22 corresponds to two rectangular pixel partitions, and an area of each of the second pixel units 22 in each of the two rectangular pixel partitions is equal. Each of the third pixel units 23 corresponds to two rectangular pixel partitions, and an area of each of the third pixel units 23 in each of the two rectangular pixel partitions is equal.

In the display panel provided by the present application, the area of each of the first pixel units 21 in each of the two rectangular pixel partitions is equal, the area of each of the second pixel units 22 in each of the two rectangular pixel partitions is equal, and the area of each of the third pixel units 23 in each of the two rectangular pixel partitions is equal, so that an effective light-emitting area of each of the first pixel units 21 in each of the rectangular pixel partitions is equal, an effective light-emitting area of each of the second pixel units 22 in each of the rectangular pixel partitions is equal, and an effective light-emitting area of each of the third pixel units 23 in each of the rectangular pixel partitions is equal, so that a display brightness of each of the rectangular pixel partitions is more uniform, which is beneficial to improving display uniformity of different areas of the display panel and improving the display effect.

In some embodiments of the present application, each of the first pixel units 21 includes two first pixel sub-units 211 independently emitting light, and areas of the two first pixel sub-units 211 in corresponding rectangular pixel partitions are equal. Each of the second pixel units 22 includes two second pixel sub-units 221 independently emitting light, and areas of the two second pixel sub-units 221 in corresponding rectangular pixel partitions are equal. Each of the third pixel units 23 includes two third pixel sub-units 231 independently emitting light, and areas of the two third pixel sub-units 231 in corresponding rectangular pixel partitions are equal.

In the display panel provided by the present application, since each of the first pixel units 21 includes the two first pixel sub-units 211 independently emitting light, and the areas of the two first pixel sub-units 211 in corresponding rectangular pixel partitions are equal, each of the rectangular pixel partitions can independently perform display functions on a basis that the display brightness of the two rectangular pixel partitions corresponding to the two first pixel sub-units 211 can be more uniform when displayed simultaneously, thereby greatly improving the resolution of the display panel.

In the display panel provided by the present application, each of the second pixel units 22 includes the two second pixel sub-units 221 independently emitting light, and the areas of the two second pixel sub-units 221 in corresponding rectangular pixel partitions are equal, so that each of the rectangular pixel partitions can independently perform display functions on a basis that the display brightness of the two rectangular pixel partitions corresponding to the two second pixel sub-units 221 can be more uniform when displayed simultaneously, thereby greatly improving the resolution of the display panel.

In the display panel provided by the present application, each of the third pixel units 23 includes the two third pixel sub-units 231 independently emitting light, and the areas of the two third pixel sub-units 231 in corresponding rectangular pixel partitions are equal, so that each of the rectangular pixel partitions can independently perform display functions on a basis that the display brightness of the two rectangular pixel partitions corresponding to the two third pixel sub-units 231 can be more uniform when displayed simultaneously, thereby greatly improving the resolution of the display panel.

It should be noted that in order to have a better display effect of an edge of the display panel, the pixel unit array 20 of the display panel provided by some embodiments of the present application further includes first edge pixel units 24 arranged in an edge area of the pixel unit array 20. Each of the first edge pixel units 24 may have a same structure as one of the first pixel sub-units 211 of the first pixel units 21. However, the structure of each of the first edge pixel units 24 is not limited by the present application. In other embodiments of the present application, the first edge pixel units may have a same structure as the first pixel units 21. Specifically, a part of the first edge pixel units may be set as dummy pixel units, and the dummy pixel units do not perform the display function during actual use.

FIG. 4 is a schematic cross-sectional view of the display panel in FIG. 3 unfolded along a line AB. Referring to FIG. 3 and FIG. 4, in some embodiments of the present application, the display panel further includes a first pixel definition layer 30 disposed on the substrate 10. The first pixel definition layer 30 includes a plurality of first dams 31, a plurality of second dams 32, and a plurality of third dams 33. One of the first dams 31 is arranged between the two first pixel sub-units 211 of each of the first pixel units 21. One of the second dams 32 is arranged between the two second pixel sub-units 221 of each of the second pixel units 22. One of the third dams 23 is arranged between the two third pixel sub-units 231 of each of the third pixel units 23. The first pixel definition layer 30 is made of a hydrophilic material.

In the display panel provided by the present application, each of the first dams 31 is configured to separate the two first pixel sub-units 211 of each of the first pixel units 21. Each of the second dams 32 is configured to separate the two second pixel sub-units 221 of each of the second pixel units 22. Each of the third dams 33 is configured to separate the two third pixel sub-units 231 of each of the third pixel units 23. Since the first pixel definition layer 30 is made of the hydrophilic material, a barrier effect of the first dams 31, the second dams 32, and the third dams 33 on solution forming the pixel unit array 20 in the inkjet printing process can be improved, thereby preventing the two first pixel sub-units 211 in each of the first pixel units 21 from generating crosstalk, preventing the two second pixel sub-units 221 in each of the second pixel units 22 from generating crosstalk, and preventing the third first pixel sub-units 231 in each of the third pixel units 23 from generating crosstalk.

In some embodiments of the present application, a length direction of each of the first dams 31 is parallel to a width direction of a corresponding one of the first pixel units 21, and a width of the corresponding one of the first pixel units 21 is defined as a first width. A length direction of each of the second dams 32 is parallel to a width direction of a corresponding one of the second pixel units 22, and a width of the corresponding one of the second pixel units 22 is defined as a second width. A length direction of each of the third dams 33 is parallel to a width direction of a corresponding one of the third pixel units 23, and a width of the corresponding one of the third pixel units 23 is defined as a third width. The first width, the second width, and the third width are equal.

In the display panel provided by the present application, the width of each of the first pixel units 21, the width of each of the second pixel units 22, and the width of each of the third pixel units 23 are all equal, so that printing parameters of the three types of the pixel units in the inkjet printing process and specifications of the printing devices can be more unified, which is beneficial to improving the printing efficiency and a printing yield.

In some embodiments of the present application, the second width, and the third width are each greater than 30 μm.

The display panel provided by the present application adopts a special arrangement of the pixel units, so that the first width, the second width, and the third width can be greater than 30 μm, far exceeding process parameters of the pixel units having a width of 15 μm in related art, thereby greatly reducing the printing difficulty in a preparation process of the pixel unit array 20 of the display panel, and improving the yield of the display panel.

In some embodiments of the present application, a length direction of each of the first pixel units 21 is perpendicular to the length direction of a corresponding one of the first dams 31. A length direction of each of the second pixel units 22 is perpendicular to the length direction of a corresponding one of the second dams 32. A length direction of each of the third pixel units 23 is perpendicular to the length direction of a corresponding one of the third dams 33. A length of the first pixel unit 21 is greater than a length of the second pixel unit 22 and less than a length of the third pixel unit 23. That is, an area of the first pixel unit 21 is greater than an area of the second pixel unit 22 and less than an area of the third pixel unit 23. In some embodiments, the lengths of the first pixel unit 21 and the second pixel unit 22 are both greater than 30 μm, and the length of the third pixel unit 23 is greater than 50 μm. A length of each of the first dams 31 is greater than a width of the corresponding one of the first pixel units 21, and a width of each of the first dams 31 is greater than or equal to 9 μm.

In some embodiments of the present application, the display panel further includes a second pixel definition layer 40 disposed on the substrate 10. The second pixel definition layer 40 and the first pixel definition layer 30 together form a plurality of pixel definition openings N. The first pixel sub-units 211, the second pixel sub-units 221, and the third pixel sub-units 231 are correspondingly arranged within the pixel definition openings N. The second pixel definition layer 40 is made of a hydrophobic material.

In the display panel provided by the present application, the second pixel definition layer 40 is made of the hydrophobic material to effectively prevent dripping ink from infiltrating side walls of the pixel definition openings N, which is beneficial to film formation of the ink of inkjet printing. Furthermore, the ink has a water-droplet shape on a contact surface of the hydrophobic material. Therefore, when an amount of the dripping ink is large, a probability that the ink diffuses and overflows outside the pixel defining openings N can be greatly reduced.

In some embodiments of the present application, a thickness of the second pixel-defining layer 40 is greater than a thickness of the first pixel-defining layer 30.

In some embodiments of the present application, the display panel further includes an anode layer 50 disposed on the substrate 10. The first pixel definition layer 30 and the second pixel definition layer 40 cover a surface of a side of the anode layer 50 facing away from the substrate 10. The pixel definition openings N expose the anode layer 50. The anode layer 50 includes a plurality of first anode units 51, a plurality of second anode units 52, and a plurality of third anode units 53. The first anode units 51 correspond to the first pixel sub-units 211. The second anode units 52 correspond to the second pixel sub-units 221. The third anode units 53 correspond to the third pixel sub-units 231. Each of the first anode units 51 includes a first guide part 511. Each of the second anode units 52 includes a second guide part 521. Each of the third anode units 52 includes a third guide part 521. Each of the rectangular pixel partitions is provided with one third guide part 531, one second guide part 521, and one third guide part 521.

In the display panel provided by the present application, since each of the rectangular pixel partitions is provided with one third guide part 531, one second guide part 521, and one third guide part 521, positions of the first guide part 511, the second guide part 521, and the third guide part 531 can be determined by using the rectangular pixel partitions as a reference object, which is beneficial to improving the efficiency of manufacturing the display panel.

In some embodiments of the present application, the first guide part 511 includes a first contact hole defining area 512. The second guide part 521 includes a second contact hole defining area 522. The third guide part 531 includes a third contact hole defining area 532. A spacing distance between the first contact hole defining area 512 and the first pixel sub-unit 211 is greater than a first preset distance. A spacing distance between the second contact hole defining area 522 and the second pixel sub-unit 221 is greater than the first preset distance. A spacing distance between the third contact hole defining area 532 and the third pixel sub-unit 231 is greater than the first preset distance.

In the display panel provided by the present application, the substrate 10 includes a driving circuit layer. The driving circuit layer is provided with via holes and a driving circuit. The driving circuit is electrically connected to the first guide part 511, the second guide part 512, and the third guide part 513 through the via holes. The via holes are provided below the first contact hole defining area 512, the second contact hole defining area 522, and the third contact hole defining area 532, respectively. The via holes may affect a film forming effect of the pixel unit array 20 during a film forming process, thereby affecting display quality of the display panel. In the present application, the spacing distance between the first contact hole defining area 512 and the first pixel sub-unit 211 is greater than the first preset distance, the spacing distance between the second contact hole defining area 522 and the second pixel sub-unit 221 is greater than the first preset distance, and the spacing distance between the third contact hole defining area 532 and the third pixel sub-unit 231 is greater than the first preset distance, so as to improve the display quality of the display panel.

In some embodiments of the present application, the first preset distance is greater than or equal to 8.5 μm.

The present application further provides a display device. The display device includes a housing and the display panel in any one of the embodiments mentioned above. The housing includes an accommodating space. The display panel is disposed inside the accommodating space.

In summary, the present application includes a display panel and a display device. The display panel includes a substrate and a pixel unit array arranged on the substrate. The pixel unit array includes a plurality of first pixel unit rows sequentially arranged along a first direction and a plurality of first pixel unit columns sequentially arranged along a second direction. Each of the first pixel unit rows includes a plurality of first pixel units sequentially arranged along the second direction. Each of the first pixel unit columns includes a plurality of first pixel units sequentially arranged along the first direction. The pixel unit array further includes a plurality of second pixel unit rows sequentially arranged along the first direction and a plurality of second pixel unit columns sequentially arranged along the second direction. Each of the second pixel unit rows includes a plurality of second pixel units and a plurality of third pixel units alternately arranged along the second direction. Each of the second pixel unit columns includes a plurality of second pixel units and a plurality of third pixel units alternately arranged along the first direction. The first pixel units in each of the first pixel unit rows are misaligned with the first pixel units of an adjacent first pixel unit row along the first direction. The first pixel units in each of the first pixel unit columns are misaligned with the first pixel units of an adjacent first pixel unit column along the second direction. One of the second pixel unit rows is arranged between every adjacent two of the first pixel unit rows. A projection of the first pixel units of one of the first pixel unit rows at least partially overlaps with a projection of the second pixel units and the third pixel units of an adjacent second pixel unit row along the first direction. One of the second pixel unit columns is arranged between every adjacent two of the first pixel unit columns. A projection of the first pixel units of one of the first pixel unit columns at least partially overlaps with a projection of the second pixel units and the third pixel units of an adjacent second pixel unit column along the second direction. The display panel adopts a specific arrangement of pixel units, so that the adjacent first pixel units are misaligned along the first direction and the second direction, the first pixel units of one of the first pixel unit rows at least partially overlap with the second pixel units and the third pixel units of the adjacent second pixel unit row along the first direction, and the first pixel units of one of the first pixel unit columns at least partially overlap with the second pixel units and the third pixel units of the adjacent second pixel unit column along the first direction. On the basis of ensuring the resolution of the display panel, a layout area of the pixel units is increased in limited layout space, thereby reducing process difficulty of forming the first pixel units, the second pixel units, and the third pixel units of the display panel by inkjet printing, and improving the production yield.

The display panel and the display device provided by the embodiments of the present application are described in detail above. The principle and implementations of the present application are described in this specification by using specific examples. The description about the foregoing embodiments is merely provided to help understand the method and core ideas of the present application. Persons of ordinary skill in the art should understand that they may still make modifications to the technical solutions described in the foregoing embodiments or make equivalent replacements to some or all technical features thereof, without departing from the scope of the technical solutions of the embodiments of the present application.

What is claimed is:

1. A display panel, comprising a substrate and a pixel unit array arranged on the substrate, and the pixel unit array comprising:
a plurality of first pixel unit rows sequentially arranged along a first direction and a plurality of first pixel unit columns sequentially arranged along a second direction, wherein each of the first pixel unit rows comprises a plurality of first pixel units sequentially arranged along the second direction, and each of the first pixel unit columns comprises a plurality of first pixel units sequentially arranged along the first direction; and
a plurality of second pixel unit rows sequentially arranged along the first direction and a plurality of second pixel unit columns sequentially arranged along the second direction, wherein each of the second pixel unit rows comprises a plurality of second pixel units and a plurality of third pixel units sequentially arranged along the second direction, and each of the second pixel unit columns comprises a plurality of second pixel units and a plurality of third pixel units sequentially arranged along the first direction;
wherein the first pixel units in each of the first pixel unit rows are misaligned with the first pixel units of an adjacent first pixel unit row along the first direction, and the first pixel units in each of the first pixel unit columns are misaligned with the first pixel units of an adjacent first pixel unit column along the second direction;
one of the second pixel unit rows is arranged between every adjacent two of the first pixel unit rows, and a projection of the first pixel units of one of the first pixel unit rows at least partially overlaps with a projection of the second pixel units and the third pixel units of an adjacent second pixel unit row along the first direction; and
one of the second pixel unit columns is arranged between every adjacent two of the first pixel unit columns, and a projection of the first pixel units of one of the first pixel unit columns at least partially overlaps with a projection of the second pixel units and the third pixel units of an adjacent second pixel unit column along the second direction.

2. The display panel according to claim 1, wherein a periphery of each of the first pixel units is provided with two second pixel units and two third pixel units, the two second pixel units and the two third pixel units are adjacent to a corresponding one of the first pixel units, and an area of at least one of each of the two second pixel units and each of the two third pixel units is greater than an area of the corresponding one of the first pixel units.

3. The display panel according to claim 2, wherein the two second pixel units are arranged symmetrically about one of diagonal lines of the corresponding one of the first pixel units, and the two third pixel units are arranged symmetrically about the other one of diagonal lines of the corresponding one of the first pixel units.

4. The display panel according to claim 1, wherein the substrate comprises a plurality of rectangular pixel partitions arranged in an array;
each of the first pixel units corresponds to two rectangular pixel partitions, and an area of each of the first pixel units in each of the two rectangular pixel partitions is equal;
each of the second pixel units corresponds to two rectangular pixel partitions, and an area of each of the second pixel units in each of the two rectangular pixel partitions is equal; and
each of the third pixel units corresponds to two rectangular pixel partitions, and an area of each of the third pixel units in each of the two rectangular pixel partitions is equal.

5. The display panel according to claim 4, wherein each of the first pixel units comprises two first pixel sub-units independently emitting light, and areas of the two first pixel sub-units in corresponding rectangular pixel partitions are equal;
each of the second pixel units comprises two second pixel sub-units independently emitting light, and areas of the two second pixel sub-units in corresponding rectangular pixel partitions are equal; and
each of the third pixel units comprises two third pixel sub-units independently emitting light, and areas of the two third pixel sub-units in corresponding rectangular pixel partitions are equal.

6. The display panel according to claim 5, further comprising:
a first pixel definition layer disposed on the substrate and comprising a plurality of first dams, a plurality of second dams, and a plurality of third dams;
wherein one of the first dams is arranged between the two first pixel sub-units of each of the first pixel units, one of the second dams is arranged between the two second pixel sub-units of each of the second pixel units, one of the third dams is arranged between the two third pixel sub-units of each of the third pixel units, and the first pixel definition layer is made of a hydrophilic material.

7. The display panel according to claim 6, wherein a length direction of each of the first dams is parallel to a width direction of a corresponding one of the first pixel units, and a width of the corresponding one of the first pixel units is defined as a first width;
a length direction of each of the second dams is parallel to a width direction of a corresponding one of the second pixel units, and a width of the corresponding one of the second pixel units is defined as a second width;
a length direction of each of the third dams is parallel to a width direction of a corresponding one of the third pixel units, and a width of the corresponding one of the third pixel units is defined as a third width; and
the first width, the second width, and the third width are equal.

8. The display panel according to claim 6, wherein the first with, the second width, and the third width are each greater than 30 μm.

9. The display panel according to claim 6, further comprising:
a second pixel definition layer disposed on the substrate, wherein the second pixel definition layer and the first pixel definition layer together form a plurality of pixel definition openings, the first pixel sub-units, the second pixel sub-units, and the third pixel sub-units are correspondingly arranged within the pixel definition openings, and the second pixel definition layer is made of a hydrophobic material.

10. The display panel according to claim 1, wherein a minimum pitch between the first pixel units and the second pixel units is defined as a, and a minimum pitch between the first pixel units and the third pixel units is defined as b, where the a is equal to the b and greater than or equal to a preset value; and
the preset value ranges from 10 μm to 15 μm.

11. A display device, comprising a housing and a display panel, wherein the housing comprises an accommodating space, and the display panel is disposed inside the accommodating space;
wherein the display panel comprises:
a plurality of first pixel unit rows sequentially arranged along a first direction and a plurality of first pixel unit columns sequentially arranged along a second direction, wherein each of the first pixel unit rows comprises a plurality of first pixel units sequentially arranged along the second direction, and each of the first pixel unit columns comprises a plurality of first pixel units sequentially arranged along the first direction; and
a plurality of second pixel unit rows sequentially arranged along the first direction and a plurality of second pixel unit columns sequentially arranged along the second direction, wherein each of the second pixel unit columns comprises a plurality of second pixel units and a plurality of third pixel units alternately arranged along the second direction, and each of the second pixel unit columns comprises a plurality of second pixel units and a plurality of third pixel units alternately arranged along the first direction;
wherein the first pixel units in each of the first pixel unit rows are misaligned with the first pixel units of an adjacent first pixel unit row along the first direction, and the first pixel units in each of the first pixel unit columns are misaligned with the first pixel units of an adjacent first pixel unit column along the second direction;
one of the second pixel unit rows is arranged between every adjacent two of the first pixel unit rows, and a projection of the first pixel units of one of the first pixel unit rows at least partially overlaps with a projection of the second pixel units and the third pixel units of an adjacent second pixel unit row along the first direction; and
one of the second pixel unit columns is arranged between every adjacent two of the first pixel unit columns, and a projection of the first pixel units of one of the first pixel unit columns at least partially overlaps with a projection of the second pixel units and the third pixel units of an adjacent second pixel unit column along the first direction.

12. The display device according to claim 11, wherein a periphery of each of the first pixel units is provided with two second pixel units and two third pixel units, the two second pixel units and the two third pixel units are adjacent to a corresponding one of the first pixel units, and an area of at least one of each of the two second pixel units and each of the two third pixel units is greater than an area of the corresponding one of the first pixel units.

13. The display device according to claim 12, wherein the two second pixel units are arranged symmetrically about one of diagonal lines of the corresponding one of the first pixel units, and the two third pixel units are arranged symmetrically about the other one of diagonal lines of the corresponding one of the first pixel units.

14. The display device according to claim 11, wherein the substrate comprising a plurality of rectangular pixel partitions arranged in an array;
each of the first pixel units corresponds to two rectangular pixel partitions, and an area of each of the first pixel units in each of the two rectangular pixel partitions is equal;
each of the second pixel units corresponds to two rectangular pixel partitions, and an area of each of the second pixel units in each of the two rectangular pixel partitions is equal; and
each of the third pixel units corresponds to two rectangular pixel partitions, and an area of each of the third pixel units in each of the two rectangular pixel partitions is equal.

15. The display device according to claim 14, wherein each of the first pixel units comprises two first pixel sub-units independently emitting light, and areas of the two first pixel sub-units in corresponding rectangular pixel partitions are equal;
each of the second pixel units comprises two second pixel sub-units independently emitting light, and areas of the two second pixel sub-units in corresponding rectangular pixel partitions are equal; and
each of the third pixel units comprises two third pixel sub-units independently emitting light, and areas of the two third pixel sub-units in corresponding rectangular pixel partitions are equal.

16. The display device according to claim 15, wherein the display panel further comprises:
a first pixel definition layer disposed on the substrate and comprising a plurality of first dams, a plurality of second dams, and a plurality of third dams;
wherein one of the first dams is arranged between the two first pixel sub-units of each of the first pixel units, one of the second dams is arranged between the two second pixel sub-units of each of the second pixel units, one of the third dams is arranged between the two third pixel sub-units of each of the third pixel units, and the first pixel definition layer is made of a hydrophilic material.

17. The display device according to claim 16, wherein a length direction of each of the first dams is parallel to a width direction of a corresponding one of the first pixel units, and a width of the corresponding one of the first pixel units is a first width;
a length direction of each of the second dams is parallel to a width direction of a corresponding one of the second pixel units, and a width of the corresponding one of the second pixel units is a second width;
a length direction of each of the third dams is parallel to a width direction of a corresponding one of the third pixel units, and a width of the corresponding one of the third pixel units is a third width; and
the first with, the second width, and the third width are equal.

18. The display device according to claim 16, wherein the first with, the second width, and the third width are each greater than 30 μm.

19. The display device according to claim 16, wherein the display panel further comprises:
a second pixel definition layer disposed on the substrate, wherein the second pixel definition layer and the first pixel definition layer together form a plurality of pixel definition openings, the first pixel sub-units, the second pixel sub-units, and the third pixel sub-units are correspondingly arranged within the pixel definition openings, and the second pixel definition layer is made of a hydrophobic material.

20. The display device according to claim 11, wherein a minimum pitch between the first pixel units and the second pixel units is a, and a minimum pitch between the first pixel units and the third pixel units is b; and
the a is equal to the b and greater than or equal to a preset value, and the preset value ranges from 10 μm to 15 μm.
